(19) United States
(12) Patent Application Publication
(10) Pub. No.: US 2004/0253809 A1
(43) Pub. Date: Dec. 16, 2004

(54) Forming a semiconductor structure using a combination of planarizing methods and electropolishing

(76) Inventors: Xiang Yu Yao, Milpitas, CA (US); Ru Kao Chang, Mountain View, CA (US); Peihaur Yih, Taiwan, NJ (US); Hui Wang, Fremont, CA (US)

Correspondence Address: Peter J Yim, Morrison & Foerster, 425 Market Street, San Francisco, CA, 94105, US

(21) Appl. No.: 10/486,982

(22) PCT Filed: Aug. 15, 2002
(86) PCT No.: PCT/US02/26167

Related U.S. Application Data
(60) Provisional application No. 60/313,066, filed on Aug. 18, 2001.

(51) Int. Cl. H01L 21/4763

(52) U.S. Cl. 438/631

(57) ABSTRACT

A method for planarizing and electropolishing a conductive layer on a semiconductor structure includes forming a dielectric layer with recessed areas and non-recessed areas on the semiconductor wafer. A conductive layer is formed over the dielectric layer to cover the recessed areas and non-recessed areas. The surface of the conductive layer is then planarized to reduce variations in the topology of the surface. The planarized conductive layer is then electropolished to expose the non-recessed area.

### CROSS-REFERENCE TO RELATED APPLICATIONS

This present application claims priority of an earlier filed provisional application U.S. Serial No. 60/313,086, entitled A METHOD TO PLANARIZE COPPER DAMASCENE STRUCTURE USING A COMBINATION OF CMP AND ELECTRO-POLISHING, filed on Aug. 17, 2001, the entire content of which is incorporated herein by reference.

### BACKGROUND

1. Field

This invention relates generally to semiconductor devices, and more particularly to a method to planarize a metal damascene structure using a combination of planarizing methods and electropolishing.

2. Description of the Related Art

Semiconductor devices are manufactured or fabricated on semiconductor wafers using a number of different processing steps to create transistor and interconnection elements. To electrically connect transistor terminals associated with the semiconductor wafer, conductive (e.g., metal) trenches, vias, or the like are formed in dielectric materials as part of the semiconductor device. The trenches and vias couple electrical signals and power between transistors, internal circuit of the semiconductor devices, and circuits external to the semiconductor device.

In forming the interconnection elements the semiconductor wafer may undergo, for example, masking, etching, and deposition processes to form the desired electronic circuitry of the semiconductor devices. In particular, multiple masking and etching steps can be performed to form a pattern of recessed areas in a dielectric layer on a semiconductor wafer that serve as trenches and vias for the interconnection lines. A deposition process may then be performed to deposit a metal layer over the semiconductor wafer to deposit metal both in the trenches and vias and also on the non-recessed areas of the dielectric layer. To isolate the pattern of recessed areas and form interconnection elements, the metal deposited on the non-recessed areas of the semiconductor wafer is removed.

Conventional methods of removing the metal deposited on the non-recessed areas of the dielectric layer on the semiconductor wafer include, for example, chemical mechanical polishing (CMP). CMP methods are widely used in the semiconductor industry to polish and planarize the metal layer within the trenches and vias with the non-recessed areas of the dielectric layer to form interconnection lines.

In a CMP process, a wafer assembly is positioned on a CMP pad located on a platen or web. The wafer assembly includes a substrate having one or more layers and/or features, such as interconnection elements formed in a dielectric layer. A force is then applied to press the wafer assembly against the CMP pad. The CMP pad and the substrate assembly are moved against and relative to one another while applying the force to polish and planarize the surface of the wafer. A polishing solution, often referred to as polishing slurry, is dispensed on the CMP pad to facilitate the polishing. The polishing slurry typically contains an abrasive and is chemically reactive to selectively remove from the wafer the unwanted material, for example, a metal layer, more rapidly than other materials, for example, a dielectric material.

Accordingly, CMP may be used to achieve global and local planarization of a surface on the wafer. Furthermore, CMP may be used to remove a layer of material in order to expose an underlying structure or layer. CMP methods, however, can have several deleterious effects on the underlying semiconductor structure because of the relatively strong mechanical forces involved. For example, as interconnection geometries move to 0.13 microns and below, there can exist a large difference between the mechanical properties of the conductive materials, for example copper, and the low k films used in typical damascene processes. For instance, the Young Modulus of a low k dielectric film may be greater than 10 orders of magnitude lower than that of copper. Consequently, the relatively strong mechanical force applied on the dielectric films and copper in a CMP process, among other things, can cause stress related defects on the semiconductor structure that include delamination, dishing, erosion, film lifting, scratching, or the like.

### BRIEF SUMMARY OF THE INVENTION

In one example, a method is provided for forming a semiconductor structure. The method includes forming a dielectric layer with recessed areas and non-recessed areas on the semiconductor wafer, forming a conductive layer over the dielectric layer to cover the recessed areas and non-recessed areas, planarizing the surface of the conductive layer to reduce variations in the topology of the surface of the conductive layer, and then electropolishing the conductive layer to expose the non-recessed areas.

The present invention is better understood upon consideration of the detailed description below in conjunction with the accompanying drawings and claims.

### BRIEF DESCRIPTION OF THE DRAWINGS

FIGS. 1A and 1B illustrate an exemplary electropolishing process of a semiconductor device;

FIGS. 2A through 2D illustrate an exemplary planarizing and electropolishing process of a semiconductor device;

FIG. 3 illustrates a flow chart of an exemplary damascene process;

FIGS. 4A and 4B illustrate exemplary topologies of a metal layer formed on a semiconductor structure that may be planarized and polished;

FIG. 5 illustrates a cross-sectional view of an exemplary chemical mechanical polishing apparatus;

FIG. 6 illustrates a cross-sectional view of an exemplary electropolishing apparatus.

### DETAILED DESCRIPTION

In order to provide a more thorough understanding of the present invention, the following description sets forth numerous specific details, such as specific materials, parameters, and the like. It should be recognized, however, that the description is not intended as a limitation on the scope of the present invention, but is instead provided to enable a better description of the exemplary embodiments.

Chemical mechanical polishing (CMP) is a known method for planarizing and polishing a semiconductor surface, however, CMP can cause stress related defects to the underlying structures such as dishing, erosion, film lifting, scratching, or the like. In contrast, electropolishing is a process to polish metal (e.g., copper) that provides a relatively stress free polishing method. However, as described below, electropolishing is an isotropic etching process, in that it etches a metal layer at approximately the same rate despite differences in height. Thus, if the profile or general shape of the topology of a metal layer is non-planar before being electropolished, then the non-planar profile or general shape of the topology of the metal layer typically remains after being electropolished.

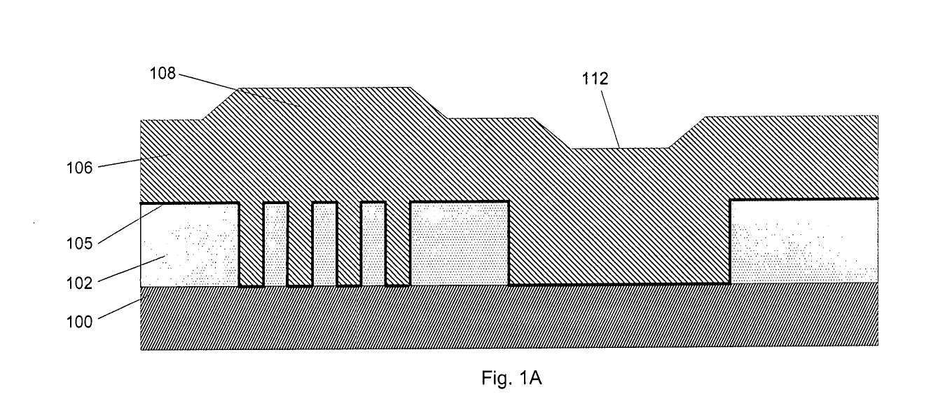

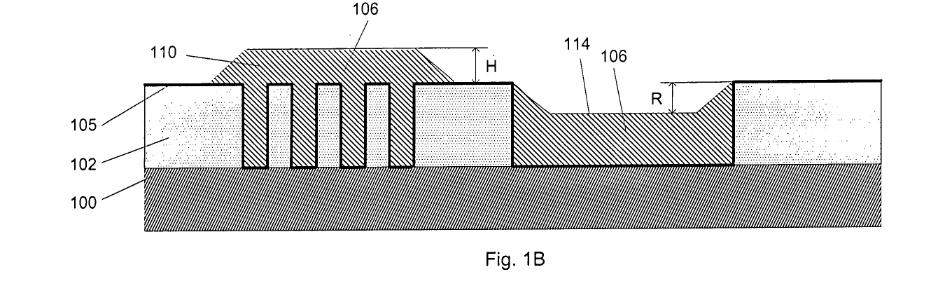

FIGS. 1A and 1B illustrate an exemplary process flow of an electropolishing method to polish a semiconductor structure that has a non-planar topology. FIG. 1A illustrates a dielectric layer 102 patterned with recessed and non-recessed areas formed over substrate 100. A barrier/seed layer 105 has been formed over the dielectric layer 102 and substrate 100. Finally, metal layer 106 has been deposited, for example, via electroplating, over barrier/seed layer 105 and covering the recessed and non-recessed areas of the dielectric layer 102. Metal layer 106 has a non-planar topology that includes a hump 108 and a recess 112 located over various structures in the dielectric layer. The non-planar topology of metal layer 106 can be caused, for example, by the plating chemistry in an electroplating process.

With reference now to FIG. 1B, metal layer 106 is typically polished back to the surface of the non-recessed areas such that metal layer 106 within the recessed areas, i.e., the trenches, is isolated to form metal interconnection lines. In general, it is desirable to have the top surface of metal layer 106 within the recessed area planar with the top surface of the non-recessed area surrounding metal layer 106 formed in the recessed area.

It should be recognized that references to planar are not intended to require or suggest that the top surface of metal layer 106 be absolutely planar with the top surface of the non-recessed area; rather, it is intended to convey that the level of the top surface of metal layer 106 is made more even with the level of the top surface of the recessed area. Thus, it is generally advantageous to reduce the variation between the level of the top surface of metal layer 106 and the level of the top surface of the recessed area.

In this example, assume that metal layer 106 is electropolished. Additionally, as depicted in FIG. 1A, assume that the profile or general shape of the topology of metal layer 106 is non-planar prior to electropolishing. As noted above, electropolishing is an isotropic etching process. As such, as depicted in FIG. 1B, the non-planar profile or general shape of the topology of metal layer 106 can remain after electropolishing.

More particularly, in this example, as depicted in FIG. 1A, assume that the topology of metal layer 106 includes hump 108 and concave portion 112 prior to electropolishing. As depicted in FIG. 1B, assume that hump 108 and concave portion 112 (FIG. 1A) remain as residue 110 and recess 114 after electropolishing. Residue 110 is a region of metal layer 106 at a height H above the dielectric layer 102. Residue 110 can cause an electrical short circuit between interconnection lines formed in the trench regions below residue 110. Recess 114 is a recess or trench in metal layer 106 where the surface of metal layer 106 within the trench is at a depth R below the surface of the dielectric layer 102. Recess 114 results in metal or copper loss within the trench that can cause a reduction of the conductance of the formed interconnection lines. Thus, as noted above, it is advantageous to reduce the variation in the height of the surface of metal layer 106 above or below the surface of the non-recessed areas.

Accordingly, in one exemplary embodiment, a metal layer formed over a patterned dielectric layer is planarized prior to electropolishing the metal layer to isolate interconnection lines. One advantage to planarizing the metal layer prior to electropolishing the metal layer back is that the metal interconnection lines can be formed in the dielectric layer with less damage to the structure underlying the metal layer than conventional planarizing techniques, and thus increase the reliability of the interconnection elements since most damage to the structure occurs when recessed metal is exposed to the CMP pad.

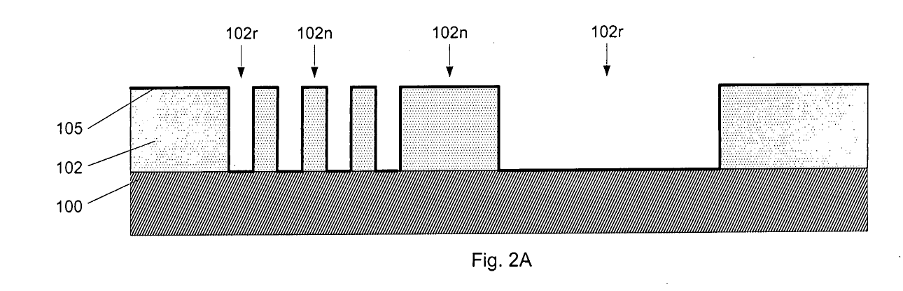

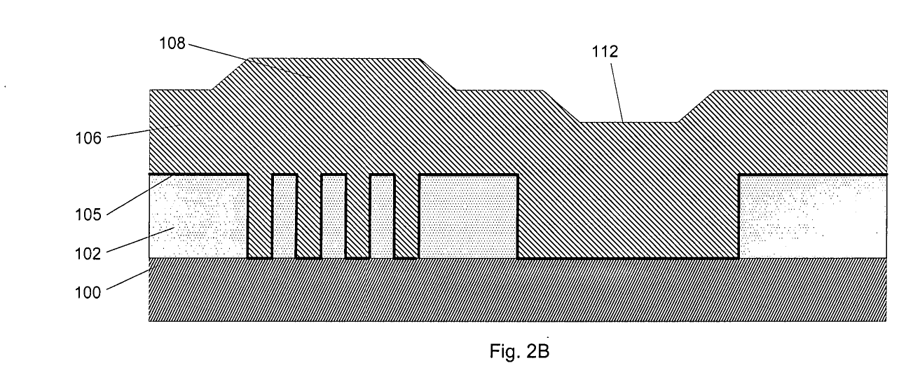

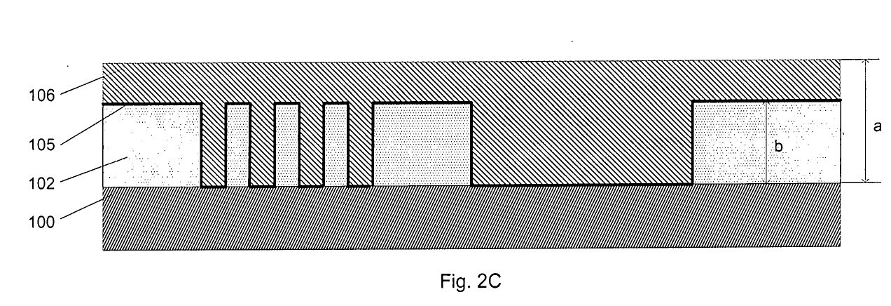

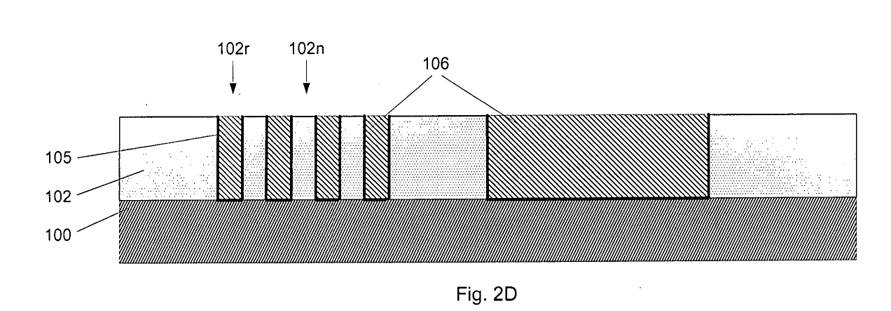

FIGS. 2A through 2D illustrate an exemplary process flow of a method to planarize and electropolish an exemplary semiconductor structure including a metal layer 106 with a non-planar topology. FIG. 2A illustrates a cross-section view of an exemplary semiconductor structure with recessed areas 102r and non-recessed areas 102n formed in a dielectric layer 102. The recessed areas 102r and non-recessed areas 102n form a pattern of interconnection lines in dielectric layer 102. Dielectric layer 102 can be conventionally deposited and formed on substrate layer 100 using any conventional deposition method, such as thermal or plasma chemical vapor deposition, spin-on, sputtering, or the like. Further, dielectric layer 102 can be patterned through known patterning methods such as photomasking, photolithography, microlithography, or the like. The dielectric material may be, for example, silicon dioxide (SiO2). For many applications it is desired to select a dielectric layer material having a low dielectric constant, often referred to as a low “k” value material. Low k value materials (i.e., less than approximately 3.0) provide better electrical isolation between interconnection lines by reducing capacitance coupling and “cross-talk” between adjacent lines. Such low k value materials include flourinated silicate glass, polyimides, fluorinated polyimides, hybrid/composites, siloxanes, organic polymers, [alpha]-C:F, Si—O—C, parylenes/fluorinated parylenes, polyterafluoroethylene, nanoporous silca, nanoporous organic, or the like.

Dielectric layer 102 is formed on substrate layer 100. Substrate layer 100 may be, for example, an underlying semiconductor wafer, previously formed dielectric layers, or other semiconductor structures. Substrate layer 100 may include, for example, silicon and/or other various semiconductor materials, such as gallium arsenide, or the like depending on the particular application.

A barrier and/or seed layer 105 may also be deposited on the dielectric layer by various methods, such as chemical vapor deposition (CVD), physical vapor deposition (PVD), atomic layer deposition (ALD), or the like, such that the barrier layer covers the patterned dielectric layer 102 including the walls of dielectric layer 102 within the recessed areas 102r. A barrier layer serves to prevent metal (e.g., copper) from diffusing into the dielectric layer 102 after the subsequent metal layer 106 deposition (FIG. 2B). Any diffusion of copper into the dielectric layer 102 may adversely increase the dielectric constant of the dielectric layer 102. Barrier/seed layer 105 can be formed of a suitable conductive material that is resistant to the diffusion of copper, such as titanium, tantalum, tungsten, titanium-nitride, tantalum-nitride, tungsten-nitride, or other suitable material. In some applications, the barrier layer can be omitted. For example, if the dielectric material is sufficiently resistant to the diffusion of the metal layer 106, or if any diffusion of metal layer 106 will not adversely affect the performance of the semiconductor device, the barrier layer may be omitted.

A seed layer is typically deposited, for example, if metal layer 106 is subsequently electroplated over dielectric layer 102. A seed layer is typically a thin layer of copper or other conductive material that metal layer 106 can be electroplated onto. Further, a single layer or material of barrier/seed layer 105 may serve as both a barrier layer and a seed layer.

With reference now to FIG. 2B, metal layer 106 is deposited on the surface of the barrier/seed layer 105, or on the dielectric layer 102 if the barrier/seed layer 105 was omitted. Metal layer 106 fills the trenches or recessed areas 102r and also covers the non-recessed areas 102n. Metal layer 106 may be deposited by PVD, CVD, ALD, electroplating, electroless plating, or any other convenient method. Metal layer 106 is, for example, copper or other suitable conductive material such as aluminum, nickel, chromium, zinc, cadmium, silver, gold, rhodium, palladium, platinum, tin, lead, iron, indium, or the like.

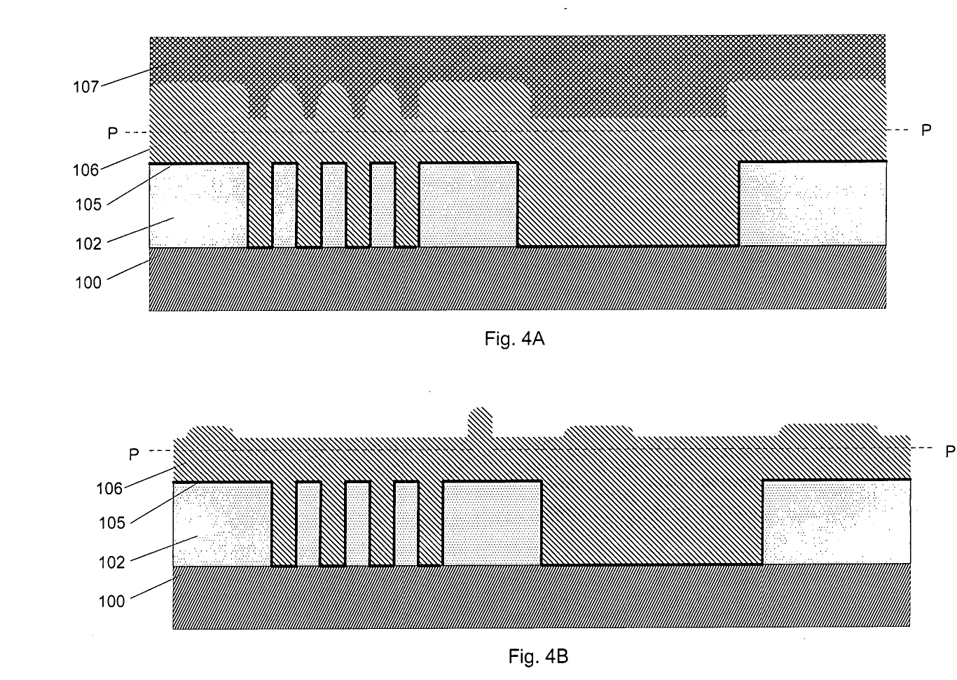

As shown in FIG. 2B, the topology of metal layer 106 may be non-planar with variations in its topology. For example, the deposition of metal layer 106 can result in a hump 108 and/or concave portion 112 above various features of dielectric layer 102. In particular, if metal layer 106 is electroplated over the dielectric layer 102, a hump 108 can form above a narrow and high-density trench region, and a concave portion 112 can form above a wide low-density trench region of dielectric layer 102. The effects can be especially prevalent in the case of electroplating metal layer 106 over dielectric layer 102 because of the plating chemistry. It should be recognized, however, that the shape and location of hump 108 and concave portion 112 are illustrative only and that other non-planar topology features of metal layer 106 are possible as described below with respect to FIGS. 4A and 4B.

With reference now to FIG. 2C, metal layer 106 is planarized to smooth or reduce features of the topology. For example, a chemical mechanical polishing (CMP) process is applied to the structure to polish and planarize metal layer 106. CMP metal layer 106 reduces the topology, i.e., hump 108, recess 112, and other non-planar topology features of the surface of metal layer 106 to smooth metal layer 106 prior to electropolishing metal layer 106. For example, the CMP process is performed to polish metal layer 106 to a first height “a” above the underlying substrate 100, where “a” is greater than a height “b,” equal to the height of dielectric layer 102. Therefore, the CMP process stops short of removing metal layer 106 from the non-recessed areas 102n of dielectric layer 102 and possibly coming in contact with dielectric layer 102. Rather, the CMP process polishes metal layer 106 to planarize and reduce variations in the topology of metal layer 106.

It should be recognized that references to planar and planarizing, specifically in reference to metal layer 106, are not intended to require or suggest that the surface of metal layer 106 be absolutely planar; rather, it is intended to convey that the surface of metal layer 106 is made more smooth or planar. Essentially, planarizing the surface of metal layer 106 reduces the variations in the topology of metal layer 106 prior to electropolishing.

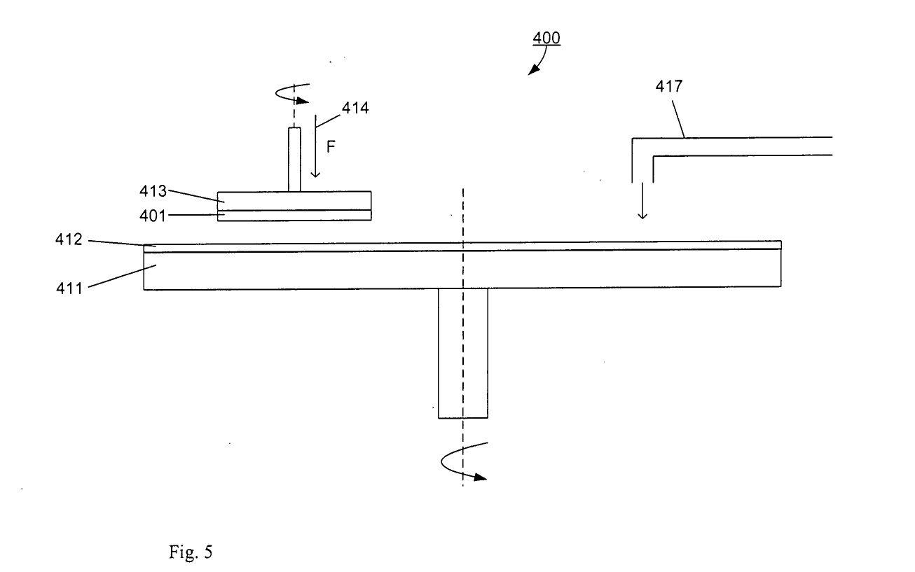

The CMP process of this exemplary method can be optimized for planarization efficiency, with less emphasis placed on preserving dielectric layer 102 and the underlying structures because the polishing pad of the CMP apparatus (FIG. 5) does not directly contact the underlying structure, such as the dielectric layer 102. For example, the stiffness or hardness of a polishing pad may be adjusted to preserve underlying dielectric layer 102. A stiff pad with a diamond tip embedded therein or the like can be used in the CMP portion of this example of the method. Further, slurry free or abrasive-free polishing processes can be used to reduce scratches in metal layer 106.

The pressure of the polishing pad can be a factor in controlling and preventing damage to the patterned dielectric layer 102, and the interconnect structure, particularly for integration schemes with copper and low k dielectric films. Typically the pressure of the polishing pad ranges from 0.1 pound-force per square inch (PSI) to 10 PSL for example 5 PSI. The thickness of metal layer 106 removed during the CMP process depends, at least in part, on the topography of the metal layer 106 formed over dielectric layer 102 and the planarization efficiency of the CMP process employed. Typically, the removal thickness is greater than or equal to the difference between a high and low point of the metal layer topology.

It should be recognized, however, that the CMP process is described herein for illustrative purposes only. Alternative methods of planarizing metal layer 106 may be used in place of, or with, the exemplary CMP process described above. For example, a sacrificial material may be added over metal layer 106 to planarize the surface above metal layer 106. The sacrificial material can be conductive or non-conductive such as spin-on-glass, photo-resist, metal alloy, metal compound, or the like. The metal layer 106 may then be planarized, for example, by etching away the sacrificial material and portions of metal layer 106. The sacrificial material and metal layer 106 should have the same or similar etch rate such that an etching process removes the sacrificial layer and metal layer 106 at similar rates. Etching the planarized metal layer 106 and the sacrificial layer at similar rates to remove the sacrificial layer and portions of metal layer 106 will result in a planarized metal layer 106. An example of the process is depicted in FIG. 4A and described below.

The etching process can be a dry etching process or a wet etching process. A dry etching process includes plasma etching, chemical vapor etching, and the like. Plasma etching sources may include high-density plasma sources such as a helicon plasma source, inductive coupled plasma source (ICP), and the like. The etching gas may include a halogen group such as chlorine based gases. Two examples of the conditions for a plasma etching process are detailed in the following tables:

TABLE I
EXEMPLARY PARAMETERS OF HIGH TEMPERATURE
PLASMA ETCHING PROCESS

| | |
|---|---|
| Plasma power: | 500 to 1500 W, preferably 800 W |
| Gas pressure: | 10 to 50 mTorr, preferably 20 mTorr |
| Wafer temperature: | 300 to 500° C., preferably 400° C. |
| Etching gases: | Chlorine (Cl₂) |

TABLE II
EXEMPLARY PARAMETERS OF LOW TEMPERATURE
PLASMA ETCHING PROCESS

| | |
|---|---|
| Step 1: | |
| Plasma power: | 500 to 1500 W, preferably 800 W |
| Gas pressure: | 10 to 50 mTorr, preferably 20 mTorr |
| Wafer temperature: | 20 to 100° C., preferably 50° C. |
| Etching gases: | Chlorine (Cl₂) |

After Step 1 the top portion of copper and copper compound will be
converted to copper chloride (CuCl₂).
Step 2:
Wet etch CuClₓ compound by using dilute HCl solution. The
concentration of HCl may be in the range of 1 to 6 percent by
weight, preferably 3 percent.

Alternatively, a planarization technique similar to those used in the flat-panel display industry to anneal the amorphous Si (a-Si) to poly-Si on glass may be employed to reflow copper after plating metal layer 106 by using a laser to mollify metal layer 106 resulting in a planarized surface. Another alternative method includes a high frequency and short pulse laser that can be beamed from a direction parallel to the substrate 100 surface to remove higher portions of the topology of metal layer 106 by evaporation. The short pulse of the laser is used to protect bulk copper and surrounding dielectrics from the effects of high temperatures generated by the laser, i.e., reduce thermobudget. The laser can be a solid state laser such as a ruby laser, Nd-glass laser, Nd:YAG (yttrium aluminum garnet, Y₃Al₅O₁₂) laser, gas laser, such as a He-Ne laser, CO₂ laser, HF laser, or the like. The laser beam can be scanned over the entire surface of substrate 100 to planarize metal layer 106. Further, a non-contact type surface topography sensor can be used as an end-point detector in such a process. Exemplary conditions for this planarization process are detailed in the following table:

TABLE III
EXEMPLARY PARAMETERS OF PULSED LASER
PLANARIZATION PROCESS

| | |
|---|---|
| Average laser power: | 100 to 5000 W |
| Pulse length: | Picoseconds to microseconds |
| Wafer temperature: | −100 to 20° C. |

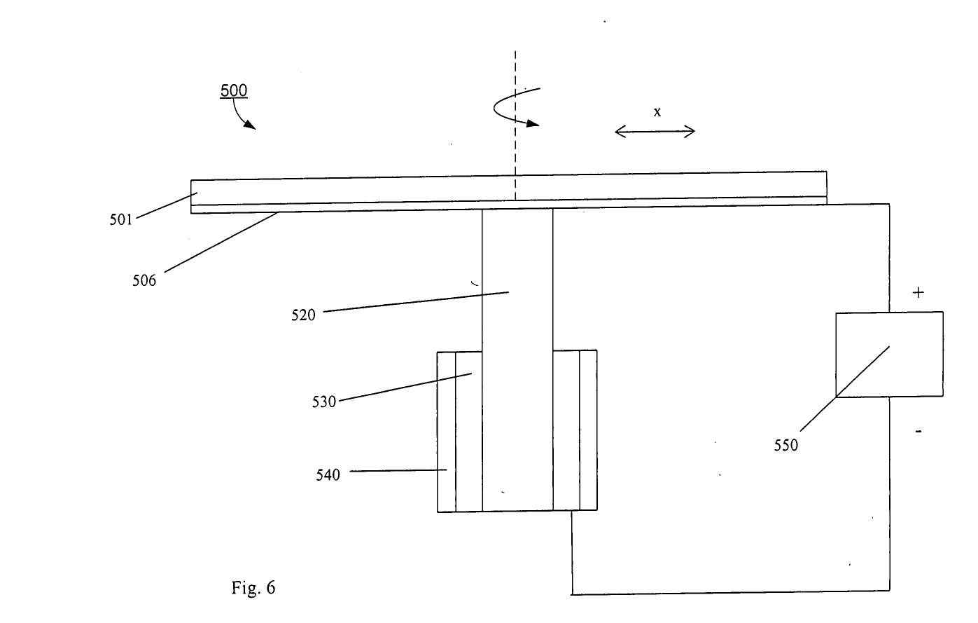

With reference now to FIG. 2D, after metal layer 106 has been planarized, metal layer 106 is electropolished. Specifically, metal layer 106 is electropolished from the non-recessed areas 102n of dielectric layer 102 such that metal layer 106 is isolated within recessed areas 102r, or trenches, to form interconnection lines. Metal layer 106 can be polished to the same height as the non-recessed areas. Alternatively, metal layer 106 can be polished to a height below the non-recessed areas. Metal layer 106 can be electropolished by an electropolishing apparatus (FIG. 6) that directs a stream of electrolyte fluid (not shown) to metal layer 106. The electrolyte fluid is, for example, any convenient electropolishing fluid, such as phosphoric acid, orthophosphoric acid (H₃PO₄), or the like.

Further, barrier/seed layer 105 is removed from the exposed regions of non-recessed areas 102n of dielectric layer 102. If layer 105 is, or includes, a seed layer, the electropolishing process that polishes metal layer 106 may remove it, for example. If layer 105 is, or includes, a barrier layer, plasma dry etching, wet etching, or the like may remove it, for example. Additionally, if the metal layer 106 was electropolished to a height less than the non-recessed areas, the non-recessed areas can also be etched at this time to planarize the surface. The following table, Table IV, provides an exemplary range of parameters that can be employed in a plasma dry etch process to remove the barrier layer:

TABLE IV
EXEMPLARY PARAMETERS OF PLASMA DRY ETCH
PROCESS

| | |
|---|---|
| Plasma Power: | 500 to 2000 W |
| Vacuum: | 30 to 100 mTorr |
| Temperature of Wafer: | approximately 20° C. |
| Gas and flow rate: | SF6 = 50 sccm (or CF4 = 50 sccm, |
| | or O₂ = 10 sccm) |
| Gas pressure: | 0.1 to 50 mTorr |
| Removal rate of TaN: | 250 nm/min |
| Removal rate of TiN: | 300 nm/min |
| Removal rate of SiO₂: | 20 nm/min |

These parameters result in a removal rate of TaN and TiN, two possible barrier layer 105 materials, greater than that of SiO₂, a possible dielectric layer 102 material. The selectivity can be selected in this manner to reduce etching or damaging the underlying dielectric layer 102 during the removal of the barrier layer 105. It should be noted, however, that other selectivities can be obtained by varying the parameters.

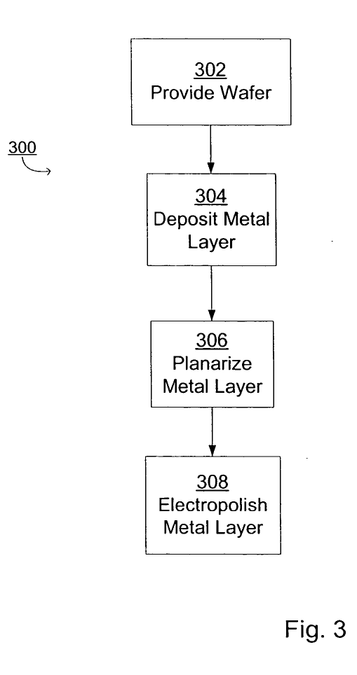

FIG. 3 is a flow chart illustrating an exemplary damascene process 300 including a planarizing process and an electroplating process. A wafer having recessed and non-recessed areas is provided in block 302. A patterned dielectric layer provided on the wafer may define the recessed and non-recessed areas. The patterned dielectric layer may be formed on underlying semiconductor structures, including other previously formed dielectric layers, a wafer, or the like. Further, the wafer may be divided up into individual dice that include recessed and non-recessed areas that will be separated at a later state of the processing into individual semiconductor devices. A metal layer is then deposited in block 304, such that the metal layer fills the recessed areas within the dielectric layer as well as covers the non-recessed areas of the dielectric layer. The metal layer is then planarized in block 306. For example, the metal layer undergoes a CMP process to planarize and smooth the topography of the metal layer. The planarized metal layer is then electropolished in block 308 to expose the non-recessed areas of the dielectric layer and isolate the metal layer within the recessed areas to form metal interconnection lines.

It should be recognized that numerous modifications can be made to the exemplary process 300 depicted in the flow chart. For example, a barrier/seed layer can be optionally added prior to the deposition of the metal layer in block 304, in which case, after non-recessed areas are exposed, the barrier/seed layer is etched from the dielectric layer. Additionally, each block in FIG. 3 can include many processes not explicitly described herein, such as masking and etching the wafer to form the recessed areas, or cleansing the metal layer before and/or after planarizing the surface. Further, the exemplary damascene process 300 is applicable to both single and dual inlaid applications.

FIGS. 4A and 4B illustrate additional exemplary topologies of metal layer 106 that may be planarized and then electropolished to form interconnection structures. With regard to FIG. 4A, metal layer 106 has a topology that roughly corresponds to the shape of the underlying dielectric layer 102. Such a topology could be created, for example, by sputtering metal layer 106 over dielectric layer 102. Metal layer 106 is then planarized, for example, by adding a sacrificial material 107 and then etching back the sacrificial material 107 and a portion of metal layer 106 such that metal layer 106 is planarized to dotted line “P.” As described above, sacrificial material 107 can be a metal, metal composites with solvent, such as copper with a solvent, spin-on glass, photo-resist, or the like. Sacrificial material 107 can be any material that has a similar etching rate as the underlying metal layer 106, and the etching process can be a conventional dry or wet etch with no selectivity between sacrificial material 107 and metal layer 106.

The location of line “P” is for illustrative purposes only, and can be adjusted up or down depending on the application and method of planarization. After the topology features of metal layer 106 have been planarized, similar to FIG. 2C, metal layer 106 is then electropolished as described above with regard to FIG. 2D.

FIG. 4B illustrates another exemplary metal layer 106 having an irregular surface topology. The irregular surface topology of metal layer 106 may be due to any number of causes ranging from the deposition method to the underlying structure. Metal layer 106 is polished similar to FIG. 4A by first planarizing the surface to line “P,” by CMP polishing, adding a sacrificial material and etching back, momentarily heating metal layer 106 with a laser or the like. Metal layer 106 is then electropolished. It should be recognized from FIGS. 4A and 4B that numerous metal layer topologies can be planarized and electropolished by this method without undue damage to the underlying dielectric layer 102.

With reference now to FIG. 5, an exemplary CMP apparatus 400 and process are described. CMP apparatus 400 may be used to planarize metal layer 106. An exemplary CMP process proceeds by pressing and rotating the surface of a wafer against a wetted polishing surface. The process is controlled through the chemical, pressure, and temperature conditions of CMP apparatus 400. Exemplary CMP apparatus 400 includes a rotatable polishing platen 411 and a polishing pad 412 mounted on polishing platen 411. CMP apparatus 400 also includes a rotatable wafer carrier 413 that positions and applies a force to a wafer 401 in the direction indicated by arrow 414. A chemical slurry is supplied to CMP apparatus 400 through nozzle 417 and dispensed onto the polishing pad 412. The chemical slurry is, for example, supplied from a temperature-controlled reservoir (not shown) through nozzle 417. Further, the chemical slurry contains a polishing agent, such as alumina, silica, or the like that is used as an abrasive agent along with other selected chemicals to polish the surface of wafer 401.

The primary parameters that affect the polishing rate are the down pressure 414 on the wafer 401 against polishing pad 412, the rotational speeds of the polishing platen 411 and wafer carrier 413, the composition and temperature of the chemical slurry, and the composition of polishing pad 412. Adjustments of these parameters permit control of the polishing rate and the planarization efficiency of CMP apparatus 400.

CMP apparatus 400 and the process described with reference to FIG. 5, are for illustrative purposes only. It should be recognized that other CMP apparatus configurations and set-ups may be employed. For example, rotatable polishing platen 411 and polishing pad 412 can be replaced with a belt that moves polishing pad 412 with respect to wafer carrier 413. Also, as will be recognized, the movement of wafer 401 with respect to polishing pad 412 can be achieved in numerous manners. Therefore, the CMP apparatus 400 depicted in FIG. 5 is not intended to be limiting of the CMP apparatus or method that may be used.

FIG. 6 illustrates an exemplary cross-sectional view of an electropolishing apparatus 500 that can be used to electropolish metal layer 506 formed on semiconductor wafer 501. Semiconductor wafer 501 may further include, for example, substrate layer 100, dielectric layer 102, and barrier/seed layer 105 (FIGS. 2A through 2D). Further, the topology of metal layer 506 will have been planarized prior to the electropolishing, for example, by CMP apparatus 400 (FIG. 5).

A nozzle 540 of the electropolishing apparatus 500 directs a stream of electrolyte fluid 520 to the surface of metal layer 506. In other examples, wafer 501 can be completely or partially immersed in electrolyte fluid 502. Electrolyte fluid 520 includes any convenient electropolishing fluid, such as phosphoric acid, orthophosphoric acid (H₃PO₄), or the like. For example, in one example the electrolyte fluid is orthophosphoric acid having a concentration between about 60 percent by weight and about 85 percent by weight. Additionally, electrolyte fluid 106 can include, for example, glycol at 10 to 40 percent (against weight of the acid). It should be recognized, however, that the concentration and composition of the electrolyte fluid can vary depending on the particular application.

As electropolishing apparatus 500 directs a stream of electrolyte fluid 520 to metal layer 506, a power supply 550 supplies opposing charges to an electrode 530 (the cathode) positioned in nozzle 540 and an electrode (the anode) coupled to metal layer 506. Power supply 550 can, for example, operate at a constant current or constant voltage mode. With power supply 550 configured to positively charge the electrolyte fluid 520 relative to metal layer 506, metal ions of metal layer 506 are removed from the surface. In this manner the stream of electrolyte fluid 520 electropolishes the portion of metal layer 506 in contact with the stream of electrolyte fluid 520.

Further, as depicted in FIG. 6, wafer 501 is rotated and translated along axis X to position the entire surface of metal layer 506 in the stream of electrolyte fluid 520 and uniformly electropolish the surface. For example, the electrolyte fluid 520 can make a spiral path along the surface of metal layer 506 by rotating wafer 501 while simultaneously translating wafer 501 in the X direction. Alternatively, wafer 501 can be held stationary while nozzle 540 is moved to apply the stream of electrolyte 520 to desired portions of metal layer 506. Further, both wafer 501 and nozzle 540 can move to apply the stream of electrolyte 520 to desired portions of metal layer 506. Exemplary descriptions of electropolishing methods and apparatus may be found in U.S. patent application Ser. No. 09/497,894, entitled METHODS AND APPARATUS FOR ELECTROPOLISHING METAL INTERCONNECTIONS ON SEMICONDUCTOR DEVICES, filed on Feb. 4, 2000, and related U.S. Pat. No. 6,395,152, entitled METHODS AND APPARATUS FOR ELECTROPOLISHING METAL INTERCONNECTIONS ON SEMICONDUCTOR DEVICES, filed on Jul., 2, 1999, both of which are incorporated herein by reference in their entirety.

Additionally, it should be recognized that other electropolishing methods and apparatus can be employed to electropolish metal layer 106. For example, wafer 501, including metal layer 506, maybe partially or fully immersed within a bath of electrolyte fluid.

The above detailed description is provided to illustrate exemplary embodiments and is not intended to be limiting. It will be apparent to those skilled in the art that numerous modification and variations within the scope of the present invention are possible. For example, numerous interconnect structures, such as combinations of dielectric layers, conductive layers, barrier layers, seed layers, and mask layers, formed in single or dual inlaid damascene implementations, can be planarized and electropolished with the methods described. Further, numerous methods of planarizing and electropolishing can be combined to planarize and electropolish the surface of the interconnection structures. It should also be apparent to those skilled in the art that metal layers with non-planar topologies, created for reasons other than those described herein, can be advantageously planarized and electropolished in accordance with the methods and apparatus described. Accordingly, the present invention is defined by the appended claims and should not be limited by the description herein.

We claim:

1. A method of forming a semiconductor structure, comprising:
forming a dielectric layer on a semiconductor wafer, wherein the dielectric layer includes recessed areas and non-recessed areas;
forming a conductive layer over the dielectric layer to cover the recessed areas and non-recessed areas;
planarizing the surface of the conductive layer to reduce variations in the topology of the surface of the conductive layer; and
electropolishing the conductive layer to expose the non-recessed areas after planarizing the surface of the conductive layer.

2. The method of claim 1, wherein the act of planarizing the surface of the conductive layer includes chemical mechanical polishing (CMP) the conductive layer.

3. The method of claim 2, wherein the CMP planarizes the surface of the conductive layer without exposing the non-recessed areas of the conductive layer.

4. The method of claim 2, wherein the CMP includes a polishing pad, and the polishing pad does not contact the non-recessed areas of the conductive layer.

5. The method of claim 2, wherein the CMP includes a slurry free polishing process.

6. The method of claim 1, wherein the act of planarizing the surface of the conductive layer includes:
forming a sacrificial material on the surface of the conductive layer, wherein said sacrificial material is planarized, and
etching the sacrificial material and a portion of the conductive layer.

7. The method of claim 6, wherein the act of etching has no selectivity between the sacrificial material and the conductive layer.

8. The method of claim 6, wherein the sacrificial material is spin-on-glass.

9. The method of claim 1, wherein forming a conductive layer includes depositing the conductive layer.

10. The method of claim 1, wherein forming a conductive layer includes electroplating the conductive layer.

11. The method of claim 1, further comprising forming a seed layer disposed between the conductive layer and the dielectric layer.

12. The method of claim 11, wherein the act of electropolishing removes portions of the seed layer from the non-recessed areas.

13. The method of claim 1, wherein the act of electropolishing includes directing a stream of electrolyte fluid to the surface of the conductive layer.

14. The method of claim 1, wherein the act of electropolishing includes immersing at least a portion of the conductive layer in electrolyte fluid.

15. The method of claim 1, further comprising forming a barrier layer disposed between the conductive layer and the dielectric layer.

16. The method of claim 15, wherein the barrier layer is removed from the non-recessed areas of the dielectric layer by plasma dry etching.

17. The method of claim 15, wherein the barrier layer is removed from the non-recessed areas of the dielectric layer by wet etching.

18. The method of claim 1, wherein the conductive layer is copper.

19. The method of claim 1, wherein the conductive layer is planarized to a first height and electropolished to a second height, wherein the second height is less than the first height.

20. The method of claim 19, wherein the second height is planar with a height of the non-recessed areas.

21. The method of claim 19, wherein the second height is less than a height of the non-recessed areas.

22. A method of making a semiconductor device, comprising:
forming a dielectric layer on a semiconductor structure, wherein the dielectric layer includes recessed areas and non-recessed areas;
forming a conductive layer to cover the dielectric layer and fill the non-recessed areas;
planarizing the conductive layer to a first height above the semiconductor structure, wherein the first height is greater than a height of the non-recessed areas; and
electropolishing the conductive layer to a second height above the semiconductor structure, wherein the second height is less than the first height.

23. The method of claim 22, wherein the second height is planar with the height of the non-recessed areas.

24. The method of claim 22, wherein the second height is less than the height of the non-recessed areas.

25. The method of claim 22, wherein the act of planarizing the conductive layer includes chemical mechanical polishing (CMP) the conductive layer.

26. The method of claim 25, wherein the CMP does not expose the structure underlying the conductive layer.

27. The method of claim 25, wherein the CMP includes a polishing pad, and the polishing pad does not contact the structure underlying the conductive layer.

28. The method of claim 25, wherein the CMP includes a slurry free polishing process.

29. The method of claim 22, wherein the act of planarizing the conductive layer includes:
forming a sacrificial material on the surface of the conductive layer, wherein said sacrificial material is planarized, and
etching the sacrificial material and the conductive layer with no selectivity between the sacrificial material and the conductive layer.

30. The method of claim 29, wherein the sacrificial material is spin-on-glass.

31. The method of claim 22, wherein forming a conductive layer includes depositing the conductive layer.

32. The method of claim 22, wherein forming a conductive layer includes electroplating the conductive layer.

33. The method of claim 22, further comprising forming a seed layer disposed between the conductive layer and the dielectric layer.

34. The method of claim 33, wherein the act of electropolishing removes a portion of the seed layer from the non-recessed areas.

35. The method of claim 22, wherein the act of electropolishing includes directing a stream of electrolyte fluid to the surface of the conductive layer.

36. The method of claim 22, wherein the act of electropolishing includes immersing at least a portion of the conductive layer in electrolyte fluid.

37. The method of claim 22, further comprising forming a barrier layer disposed between the conductive layer and the dielectric layer.

38. The method of claim 37, wherein the barrier layer is removed from the non-recessed areas of the dielectric layer by plasma dry etching.

39. The method of claim 37, wherein the barrier layer is removed from the non-recessed areas of the dielectric layer by wet etching.

40. The method of claim 22, wherein the conductive layer is copper.

41. A method for making an interconnection structure, comprising:
forming a semiconductor structure, wherein the semiconductor structure is patterned with openings to form interconnection lines;
forming a conductive layer over the semiconductor structure and within the openings;
planarizing the surface of the conductive layer to reduce non-planar variations; and
electropolishing the planarized conductive layer to isolate the conductive layer within the openings.

42. The method of claim 41, wherein the semiconductor structure includes:
a dielectric layer with openings formed therein.

43. The method of claim 42, wherein the semiconductor structure further includes:
a barrier layer formed between the dielectric layer and the conductive layer.

44. The method of claim 43, wherein the barrier layer is removed from portions of the dielectric layer by plasma dry etching.

45. The method of claim 43, wherein the barrier layer is removed from portions of the dielectric layer by wet etching.

46. The method of claim 42, further comprising forming a seed layer disposed between the conductive layer and the dielectric layer.

47. The method of claim 46, wherein the act of electropolishing removes a portion of the seed layer.

48. The method of claim 41, wherein the act of planarizing the surface of the conductive layer includes chemical mechanical polishing (CMP) the conductive layer.

49. The method of claim 48, wherein the CMP does not expose the structure underlying the conductive layer.

50. The method of claim 48, wherein the CMP includes a polishing pad, and the polishing pad does not contact the structure underlying the conductive layer.

51. The method of claim 48, wherein the CMP includes a slurry free polishing process.

52. The method of claim 41, wherein the act of planarizing the surface of the conductive layer includes:
forming a sacrificial material on the surface of the conductive layer, wherein said sacrificial material is planarized, and
etching the sacrificial material and a portion of the conductive layer with no selectivity between the sacrificial material and the conductive layer.

53. The method of claim 52, wherein the sacrificial material is spin-on-glass.

54. The method of claim 41, wherein forming a conductive layer includes depositing the conductive layer.

55. The method of claim 41, wherein forming a conductive layer includes electroplating the conductive layer.

56. The method of claim 41, wherein the act of electropolishing includes directing a stream of electrolyte fluid to the surface of the conductive layer.

57. The method of claim 41, wherein the act of electropolishing includes immersing at least a portion of the conductive layer in electrolyte fluid.

58. The method of claim 41, wherein the conductive layer is copper.

59. A semiconductor structure, comprising:
a conductive layer; and
a dielectric layer having recessed areas and non-recessed areas,
wherein the conductive layer fills the non-recessed areas to form interconnection lines, and
the non-recessed areas are exposed by planarizing and then electropolishing the surface of the conductive layer.

60. The structure of claim 59, wherein the conductive layer is planarized by chemical mechanical polishing (CMP).

61. The structure of claim 60, wherein the CMP does not expose the non-recessed areas of the dielectric layer.

62. The structure of claim 60, wherein the conductive layer is planarized by:
forming a planar sacrificial material on the surface of the conductive layer, and
etching the sacrificial material and a portion of the conductive layer.

63. The structure of claim 62, wherein the act of etching has no selectivity between the sacrificial material and the conductive layer.

64. The method of claim 62, wherein the sacrificial material includes spin-on-glass.

65. The method of claim 62, wherein the sacrificial material includes photo-resist.

66. The method of claim 62, wherein the sacrificial material includes metal.

67. A semiconductor structure formed in accordance with the method of claim 1.

68. A semiconductor device formed in accordance with the method of claim 22.

69. An interconnect structure formed on a semiconductor wafer in accordance with the method of claim 41.
